(19) United States
(12) Patent Application Publication
(10) Pub. No.: US 2015/0221848 A1
(43) Pub. Date: Aug. 6, 2015

(54) THERMOELECTRIC DEVICE AND METHOD OF MANUFACTURING THE SAME

(71) Applicant: Electronics and Telecommunications Research Institute, Daejeon (KR)

(72) Inventors: Taehyoung ZYUNG, Daejeon (KR); Moon Gyu JANG, Daejeon (KR)

(73) Assignee: Electronics and Telecommunications Research Institute, Daejeon (KR)

(21) Appl. No.: 14/445,132

(22) Filed: Jul. 29, 2014

(30) Foreign Application Priority Data
Feb. 6, 2014 (KR) 10-2014-0013705

(51) Int. Cl. H01L 35/32; H01L 35/34

(52) U.S. Cl. CPC H01L 35/32; H01L 35/34

(57) ABSTRACT

Provided are a thermoelectric device and a method of manufacturing the same. The thermoelectric device includes a substrate, a first electrode having a first comb shape connected to one side of the substrate and open to the other side of the substrate, a second electrode having a second comb shape connected to the other side of the substrate and open to the one side of the substrate and inserted into the first electrode, and first and second thermoelectric medium layers disposed between the first electrode and the second electrode and alternately disposed in a direction apart from the substrate.

### CROSS-REFERENCE TO RELATED APPLICATIONS

This U.S. non-provisional patent application claims priority under 35 U.S.C. §119 of Korean Patent Application No. 10-2014-0013705, filed on Feb. 6, 2014, the entire contents of which are hereby incorporated by reference.

### BACKGROUND OF THE INVENTION

The present invention disclosed herein relates to an electric device and a method of manufacturing the same, and more particularly, to a thermoelectric device and a method of manufacturing the same.

Recently, as energy sources are exhausted and sudden rises of oil prices have occurred, necessities for developing new energy sources and alternative energy or clean energy for carbon-based energy sources mainly responsible for global warming such as unusual high temperature greatly increase. Solar energy most spotlighted as clean energy is unlimitedly supplied and there is no royalty, which makes it popular. On the contrary, developing energies using other new regeneration energies such as wind power, tidal power, and geothermal heat have not been performed globally. Particularly, solar energies or other new generation energies are slightly unsuitable for electronic communication devices or components such as cellular phones, laptop computers, and radio frequency identifications (RFID). To generate new generation energies or clean energies suitable for electronic communication devices, it is necessary to enable miniaturization and simultaneously with supplying full power for being used in small-sized devices. Currently, there are scarcely present energy sources capable of satisfying such conditions. Although fuel cells, bio cells, etc. have been researched, there are many limitations in stability and reproducibility. On the contrary, thermoelectric generation technology of generating electric energy from other peripheral heat energies such as heat of a human body, that is, body heat and solar or other peripheral heat energies is appropriate for miniaturization. The thermoelectric generation technology is appropriate for being applied to information technology (IT) devices needing small power and may increase a life of devices by supplying a proper amount of power necessary for an emergency if necessary.

Thermo-electric energy conversion efficiency of a material greatly depends on a figure of merit ZT value of the material, which is shown as Equation 1 as follows.

ZTₘ=α²σT/κ Equation (1)

Herein, α indicates Seebeck coefficient, σ indicates electrical conductivity, and T indicates an absolute temperature. κ indicates thermal conductivity, a subscript m indicates a material, and Seebeck coefficient is also referred to as thermo power or thermoelectric power and may have a negative or positive value.

A constant indicating a ratio ΔV/ΔT of a change of voltage to a change of a temperature, as unique characteristics of material, generally has a small value in metal and a greater value in semiconductor. In equation 1, a numerator α²σ is a power factor and generally relates to carrier concentration to allow ZT to increase. At the same concentration, a material having a carrier with great mobility is effective to have high electric conductivity. Since two materials of an n-type and a p-type are necessary for a thermoelectric device not one type material, a ZT value only for a single material is not significant. Accordingly, a ZT value of a device, different from a ZT value only of a material, is given as Equation 2 as follows.

ZT_{d}=(αₚ²−αₙ²)T/[(ρₙκₙ)^{1/2}+(ρₚκₚ)^{1/2}] Equation (2)

Herein, a subscript d indicates a device. ZT_{d} indicates a figure of merit ZT value of a device. αp and an indicate p-type and n-type Seebeck coefficients. ρₙκₙ and ρₚκₚ indicate products of n-type and p-type electric resistances and thermal conductivities.

Efficiency of an thermoelectric device is directly proportional to the ZTd value. According to Equation 2, when a difference in thermopower between the p-type material and the n-type material is great and the two materials have small thermal conductivity and electric resistance, ZT values may be great.

As shown in Equation 2, to allow the ZT to have a great value, most basically, electric conductivity is to be great and thermal conductivity is to be low. To allow a material to have such properties, it is necessary to satisfy several conditions. Primarily, a material is in a glassy state making phonons related to thermal conductivity difficult to move. On the contrary, with respect to electrons related to electric conductivity, a state having a crystalline structure is most desirable. Secondarily, in the material, there are present two carriers such as electrons and holes. Depending on n-type and p-type characteristics of the material, any one becomes a majority carrier and another becomes a minority carrier. To minimize effects of the minority carrier, it is necessary that a band gap is fully great such as about 10 k_{B}T. Particularly, to be used at a high temperature, it is necessary to minimize the effects of the minority carrier. Thirdly, thermal stability is to be well. That is, while increasing a temperature such as thermal annealing or operating at a high temperature for a long time, it is necessary to decrease deterioration in performance caused by atomic diffusion in the material and interdiffusion in a contact with an electrode. Fourthly, to increase electric conductivity, the material needs a carrier with great mobility. Fifthly, thermal conductivity is formed of portions given with electrons and phonons. The portion given with electrons is proportional to electric conductivity as Wiedemann-Franz relationship, and portions given with phonons has a smaller value as a mean free path of phonon is smaller. Accordingly, it is necessary that the electric conductivity of the material is not too great and the mean free path of the phonons is small. To satisfy the conditions, there is expended effort on development of various thermoelectric novel materials and device structures.

Up to now, as material for generating thermoelectric energy, a compound of bismuth (Bi) and telluride (Te) are used most. In addition thereto, elements such as Yb, Pb, Cs, and Si and compounds according to various composition such as Te and Ge have been researched as the material. Inorganic materials as described above, firstly, are generally heavy metals and have a bad effect on environments. Secondarily, a compound changes in composition and has a superlattice structure, thereby increasing synthetic energy of the compound. Thirdly, high energy is necessary for manufacturing a module. Lastly, it is difficult to separate or reuse. To overcome such limitations, a method of using conducting polymers with relatively lower prices, and low synthetic and production energy, and abundant raw materials are on the rise. Although thermal conductivity is low, electric conductivity is still low. Quite recently, a result of investigation, in which it is possible to increase conversion efficiency using silicon nano wires, has been reported. A theoretical research result, in which materials such as graphene may provide very high conversion efficiency, has been reported. A material having a nanostructure may diffuse phonons having an intermediate wavelength or higher, thereby reducing thermal conductivity due to lattices. Accordingly, a material having a superlattice structure of Bi2Te3/Sb2Te3 has been developed. Also, as described above, recently, a study for applying silicon nano wires to a thermoelectric device has been performed.

Although developments of various thermoelectric materials have been vigorously performed, there is not yet present a commercialized material having performance beyond bismuth materials. Since a structure of a thermoelectric device using bismuth materials, as described above, is formed of a p-type thermoelectric bar and an n-type thermoelectric bar are two-dimensionally connected in series, a process is complicated to increase manufacturing costs. An access to a low-price process is necessary.

### SUMMARY OF THE INVENTION

The present disclosure provides a thermoelectric device having a vertical stack structure and a method of manufacturing the same.

The present disclosure also provides a thermoelectric device capable of minimizing a unit area and a method of manufacturing the same.

Embodiments of the inventive concept provide thermoelectric devices including a substrate, a first electrode having a first comb shape connected to one side of the substrate and open to another side of the substrate in a cross-sectional view, a second electrode having a second comb shape connected to the other side of the substrate and open to the one side of the substrate, the second electrode inserted into the first electrode, and first and second thermoelectric medium layers disposed between the first electrode and the second electrode and alternately disposed in a direction apart from the substrate.

In some embodiments, the first electrode may include first horizontal electrode layers parallel to the substrate and a first vertical electrode connecting the first horizontal electrode layers in a direction vertical to the substrate.

In other embodiments, the first electrode may further include first edge electrode layers between the first horizontal electrode layers and the first vertical electrode.

In still other embodiments, the second electrode may include second horizontal electrode layers parallel to the substrate and disposed between the first horizontal electrode layers and a second vertical electrode parallel to the first vertical electrode and connecting the second horizontal electrode layers in the direction vertical to the substrate.

In even other embodiments, the second electrode may further include second edge electrode layers between the second horizontal electrode layers and the second vertical electrode.

In yet other embodiments, the thermoelectric device may further include an insulating layer between the first electrode and the second electrode.

In further embodiments, the insulating layer may include a first insulating layer between the first edge electrode layers and a second insulating layer between the second edge electrode layers.

In still further embodiments, the first and second thermoelectric medium layers may be alternately disposed between the first horizontal electrode layers and the second horizontal electrode layers, respectively.

In even further embodiments, the first horizontal electrode layers may include a first lower horizontal electrode layer between the substrate and the first thermoelectric medium layers and first upper horizontal electrode layers between the second thermoelectric medium layers and the first thermoelectric medium layer.

In yet further embodiments, the insulating layer may further include an interlayer dielectric and the interlayer dielectric may include a first interlayer dielectric between the first horizontal electrode layers and a second interlayer dielectric between the second horizontal electrode layers.

In much further embodiments, the first horizontal electrode layers may include first lower horizontal electrode layers between the substrate and the first thermoelectric medium layers or between the second interlayer dielectric and the first thermoelectric medium layers and first upper horizontal electrode layers between the second thermoelectric medium layers and the second interlayer dielectric.

In still much further embodiments, the first edge electrode layers may include first lower edge electrode layers connecting the first lower horizontal electrode layers to the first vertical electrode and first upper edge electrode layers connecting the first upper horizontal electrode layers to the first vertical electrode.

In even much further embodiments, the second horizontal electrode layers may include second lower horizontal electrode layers between the first thermoelectric medium layers and the first interlayer dielectrics and second upper horizontal electrode layers between the first interlayer dielectrics and the second thermoelectric medium layers.

In yet much further embodiments, the second edge electrode layers may include second lower edge electrode layers connecting the second lower horizontal electrode layers to the second vertical electrode and second upper edge electrode layers connecting the second upper horizontal electrode layers to the second vertical electrode.

In further embodiments, the first insulating layer may include a first sidewall insulating layer disposed between one sidewalls of the first thermoelectric medium layers, the first low temperature-horizontal electrode layers and the second thermoelectric medium layers and the first vertical electrode and connected to one side of the first interlayer dielectric and a first edge insulating layer disposed between one side of the second interlayer dielectric and the first vertical electrode.

In still further embodiments, the second insulating layer may include a second edge insulating layer disposed between other sidewalls of the second thermoelectric medium layers, the first high temperature-horizontal electrode layers and the first thermoelectric medium layers and the second vertical electrode and connected to another side of the second interlayer dielectric and a second sidewall insulating layer disposed between another side of the second interlayer dielectric and the second vertical electrode.

In other embodiments of the inventive concept, thermoelectric devices include a plurality of first and second horizontal electrodes alternately stacked on a substrate, a plurality of first and second thermoelectric medium layers alternately disposed between the first and second horizontal electrodes, a first vertical electrode connecting the first horizontal electrodes, and a second vertical electrode parallel to the first vertical electrode and connecting the second horizontal electrodes.

In some embodiments, the thermoelectric device may further include a first insulating layer between the second horizontal electrodes and the first vertical electrode and a second insulating layer between the first horizontal electrodes and the second vertical electrode.

In still other embodiments of the inventive concept, methods of manufacturing a thermoelectric device include forming first thermoelectric medium layers on first horizontal electrode layers, forming second horizontal electrode layers on the first thermoelectric medium layers, forming second thermoelectric medium layers on the second horizontal electrode layers, repetitively forming the first horizontal electrode layers, the first thermoelectric medium layers, the second horizontal electrode layers, the second thermoelectric medium layers, and the first horizontal electrode layers on the second thermoelectric medium layers, forming a first insulating layer on respective sidewalls of the first thermoelectric medium layer, the second horizontal electrode layer, and the second thermoelectric medium layer, forming first edge electrode layers and a first vertical electrode on one sidewalls of the first horizontal electrode layers exposed from the first insulating layer and the first insulating layer, forming a second insulating layer on respective other sidewalls of the first horizontal electrode layers, the first thermoelectric medium layers, and the second thermoelectric medium layers, and forming second edge electrode layers and a second vertical electrode on other sidewalls of the second horizontal electrode layers exposed from the second insulating layer and the second insulating layer.

In some embodiments, the method may further include forming first interlayer dielectrics between the first horizontal electrode layers and forming second interlayer dielectrics between the second horizontal electrode layers.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a cross-sectional view of a thermoelectric device according to an embodiment of the inventive concept;

FIGS. 2 to 10 are cross-sectional views illustrating a process of manufacturing the thermoelectric device of FIG. 1;

FIG. 11 is a cross-sectional view of a thermoelectric device according to another embodiment of the inventive concept; and

FIGS. 12 to 21 are cross-sectional views illustrating a process of manufacturing the thermoelectric device of FIG. 11.

### DETAILED DESCRIPTION OF PREFERRED EMBODIMENTS

Hereinafter, exemplary embodiments of the inventive concept will be described in detail with reference to the attached drawings. Advantages and features of the inventive concept and a method of achieving the same will be specified with reference to the embodiments that will be described together with the attached drawings. However, the inventive concept is not limited to the embodiments described below and may have variously modified forms. The embodiments that will be described hereafter are provided to allow the disclosure to be thoroughgoing and perfect and to allow a person of ordinary skills in the art to fully understand the scope of the present invention. The present invention will be defined only by the scope of following claims. Throughout the entire specification, like reference numerals designate like elements.

Terms used herein are to describe the embodiments but will not limit the inventive concept. As used herein, the singular forms are intended to include the plural forms as well, unless the context clearly indicates otherwise. It will be further understood that the terms “comprises” and/or “comprising” used herein specify the presence of stated features or components, but do not preclude the presence or addition of one or more other features or components. Also, as just exemplary embodiments, reference numerals shown according to an order of description are not limited thereto.

### Embodiment 1

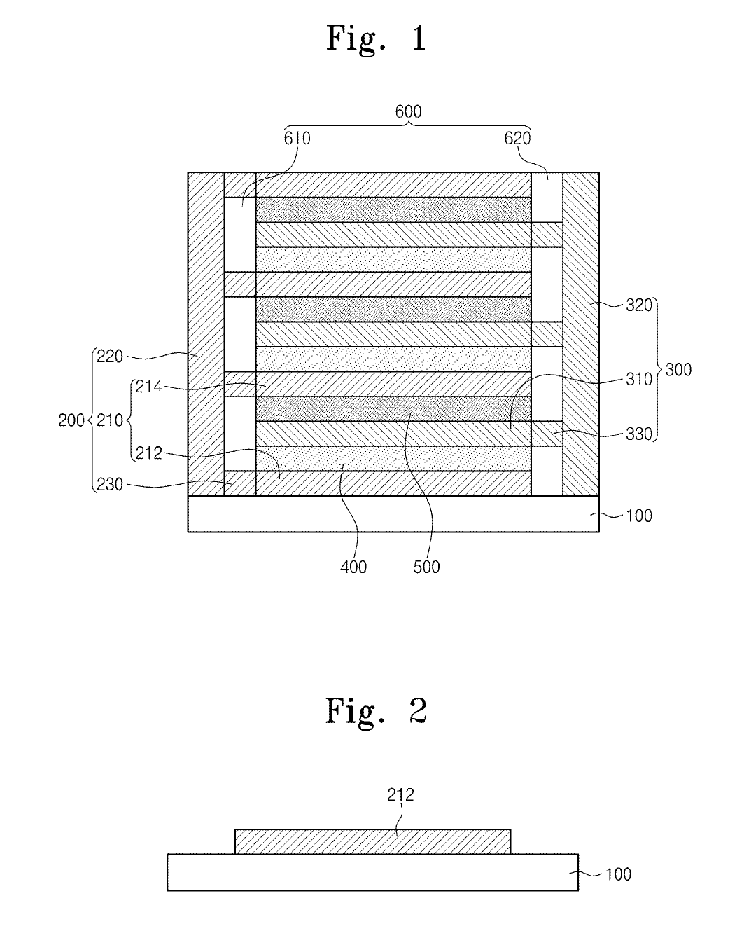

### FIG. 1 is a cross-sectional view of a thermoelectric device according to an embodiment of the inventive concept.

Referring to FIG. 1, the thermoelectric device may include a substrate 100, a high temperature electrode 200, a low temperature electrode 300, first thermoelectric medium layers 400, second thermoelectric medium layers 500, a first insulating layer 610, and a second insulating layer 620.

The substrate 100 may be one of a silicon substrate, a glass substrate, a metal substrate, a silicon on insulator (SOI) substrate, and a substrate stacked with a combination thereof.

The high temperature electrode 200 may be disposed on the substrate 100. The high temperature electrode 200 may include a metal layer or metal-oxide layer having conductivity. For example, the high temperature electrode 200 may include at least one of aluminum (Al), copper (Cu), tungsten (W), titanium (Ti), silver (Ag), gold (Ag), platinum (Pt), nickel (Ni), carbon (C), molybdenum (Mo), tantalum (Ta), iridium (Ir), ruthenium (Ru), zinc (Zn), tin (Sn), and Indium (In).

As an example, the high temperature electrode 200 may have a comb shape connected to one side of the substrate 100 and open to another side of the substrate 100 in a cross-sectional view. For example, the high temperature electrode 200 may include high temperature-horizontal electrode layers 210, a high temperature-vertical electrode 220, and high temperature edge electrode layers 230.

The high temperature-horizontal electrode layers 210 may be disposed to be parallel to the substrate 100, the first thermoelectric medium layers 400, and the second thermoelectric medium layers 500.

The high temperature-vertical electrode 220 may be disposed adjacently to respective one sidewalls of the high temperature-horizontal electrode layers 210. The high temperature-vertical electrode 220 may connect the high temperature-horizontal electrode layers 210. The high temperature-vertical electrode 220 may be disposed to be vertical to the high temperature-horizontal electrode layers 210 and the substrate 100.

The high temperature edge electrode layers 230 may connect the high temperature-vertical electrode 220 to the high temperature-horizontal electrode layers 210. The high temperature-vertical electrode 220 and the high temperature edge electrode layers 230 may connect respective one sides of the high temperature horizontal electrode layers 210. Other ends of the high temperature-horizontal electrode layers 210 may be open from the high temperature-vertical electrode 220.

The first thermoelectric medium layers 400 may be disposed on the high temperature-horizontal electrode layers 210. According to the embodiment, the first thermoelectric medium layers 400 may include an n-type material. However, the first thermoelectric medium layers 400 are not limited thereto and may be variously modified. The first thermoelectric layers 400 may include a p-type material. For example, the first thermoelectric medium layers 400 may include one of an organic material, a polymer, an oxide, and a semiconductor. The semiconductor may include one of bismuth or antimony alloy, silicon germanium, and silicon.

The low temperature electrode 300 may be disposed on the substrate 100 and the first thermoelectric medium layer 400. The low temperature electrode 300 may include a metal layer or a metal oxide layer. For example, the low temperature electrode 300 may include at least one of aluminum (Al), copper (Cu), tungsten (W), titanium (Ti), silver (Ag), gold (Ag), platinum (Pt), nickel (Ni), carbon

(C), molybdenum (Mo), tantalum (Ta), iridium (Ir), ruthenium (Ru), zinc (Zn), tin (Sn), and Indium (In).

As an example, the low temperature electrode 300 may have a comb shape connected to the other side of the substrate 100 and open to the one side of the substrate 100. The low temperature electrode 300 may be alternately inserted into the high temperature electrode 200. For example, the low temperature electrode 300 may include low temperature-horizontal electrode layers 310, a low temperature-vertical electrode 320, and low temperature edge electrode layers 330.

The low temperature-horizontal electrode layers 310 may be disposed on the first thermoelectric medium layers 400. The first thermoelectric medium layers 400 may be disposed between the high temperature-horizontal electrode layers 210 and the low temperature-horizontal electrode layers 310, respectively.

The low temperature-vertical electrode 320 may be disposed adjacently to other sidewalls of the low temperature-horizontal electrode layers 310. The low temperature-vertical electrode 320 may connect the low temperature horizontal electrode layers 310. The low temperature-vertical electrode 320 may be disposed to be vertical to the low temperature-horizontal electrode layers 310 and the substrate 100.

The low temperature edge electrode layers 330 may connect the low temperature-horizontal electrode layers 310 to the low temperature-vertical electrode 320. The low temperature edge electrode layers 330 and the low temperature-vertical electrode 320 may connect respective one sides of the low temperature-horizontal electrode layers 310.

The first electrode medium layers 400 and the second thermoelectric medium layers 500 may be disposed between the high temperature electrode 200 and the low temperature electrode 300 to be spaced from one another. The first thermoelectric medium layers 400 and the second thermoelectric medium layers 500 may be disposed more alternately as further from the substrate 100.

The second thermoelectric medium layers 500 may be disposed on the low temperature-horizontal electrode layers 310. The second thermoelectric medium layers 500 may be disposed between the low temperature-horizontal electrode layers 310 and the high temperature-horizontal electrode layers 210. The second thermoelectric layers 500 may include a p-type material, but not limited thereto and may be modified. For example, when the first thermoelectric medium layers 400 are a p-type material, the second thermoelectric layers 500 may include an n-type material. For example, the second thermoelectric medium layers 500 may include one of an organic material, a polymer, an oxide, and a semiconductor.

The first insulating layer 610 may be disposed between the high temperature edge electrode layers 230. The first insulating layers 610 may be disposed between one sidewalls of the first thermoelectric medium layers 400, the low temperature electrode layers 310, and the second thermoelectric medium layers 500 and the high temperature-vertical electrode 220. The first insulating layer 610 may include a dielectric such as a silicon oxide film, a silicon nitride film, a silicon oxy-nitride film, an aluminum oxide film, and a titanium oxide film.

The second insulating layer 620 may be disposed between the low temperature edge electrode layers 330. The second insulating layers 620 may be disposed between other sidewalls of the high temperature-horizontal electrode layers 210, the first thermoelectric medium layers 400, and the second thermoelectric medium layers 500 and the low temperature-vertical electrode 320. The second insulating layer 620 may include a dielectric such as a silicon oxide film, a silicon nitride film, a silicon oxy-nitride film, an aluminum oxide film, and a titanium oxide film.

The high temperature electrode 200 and the low temperature electrode 300 may be alternately disposed between the first thermoelectric medium layers 400 and the second thermoelectric medium layers 500. The high temperature electrode 200, the low temperature electrode 300, the first thermoelectric medium layers 400, and the second thermoelectric medium layers 500 may be stacked to be vertical to the substrate 100. Accordingly, the high temperature electrode 200, the low temperature electrode 300, the first thermoelectric medium layers 400, and the second thermoelectric medium layers 500 may minimize a unit cell area of the thermoelectric device.

A method of manufacturing the thermoelectric device of FIG. 1 formed as described above will be described as follows.

FIGS. 2 to 10 are cross-sectional views illustrating a process of manufacturing the thermoelectric device of FIG. 1.

Referring to FIG. 2, a lower high temperature-horizontal electrode layer 212 is formed on the substrate 100. The lower high temperature-horizontal electrode layer 212 may be formed through physical vapor deposition or chemical vapor deposition.

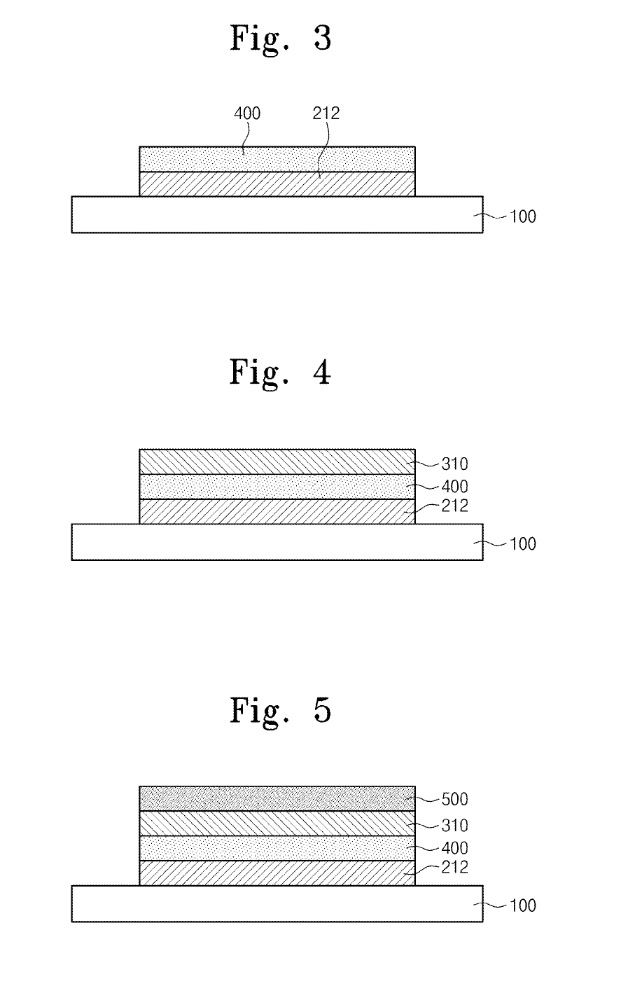

Referring to FIG. 3, the first thermoelectric medium layer 400 is formed on the lower high temperature-horizontal electrode layer 212. The first thermoelectric medium layer 400 may be formed through spin casting, spin coating, chemical vapor deposition, or printing.

Referring to FIG. 4, the low temperature-horizontal electrode layer 310 is formed on the first thermoelectric medium layer 400. The low temperature-horizontal electrode layer 310 may include a metal layer or a metal oxide layer formed through physical vapor deposition or chemical vapor deposition.

Referring to FIG. 5, the second thermoelectric medium layer 500 is formed on the low temperature-horizontal electrode layer 310. The second thermoelectric medium layer 500 may be formed through spin casting, spin coating, chemical vapor deposition, or printing.

Referring to FIG. 6, an upper high temperature-horizontal electrode layer 214 is formed on the second thermoelectric medium layer 500. The upper high temperature-horizontal electrode layer 214 may include a metal layer or a metal oxide layer formed through physical vapor deposition or chemical vapor deposition.

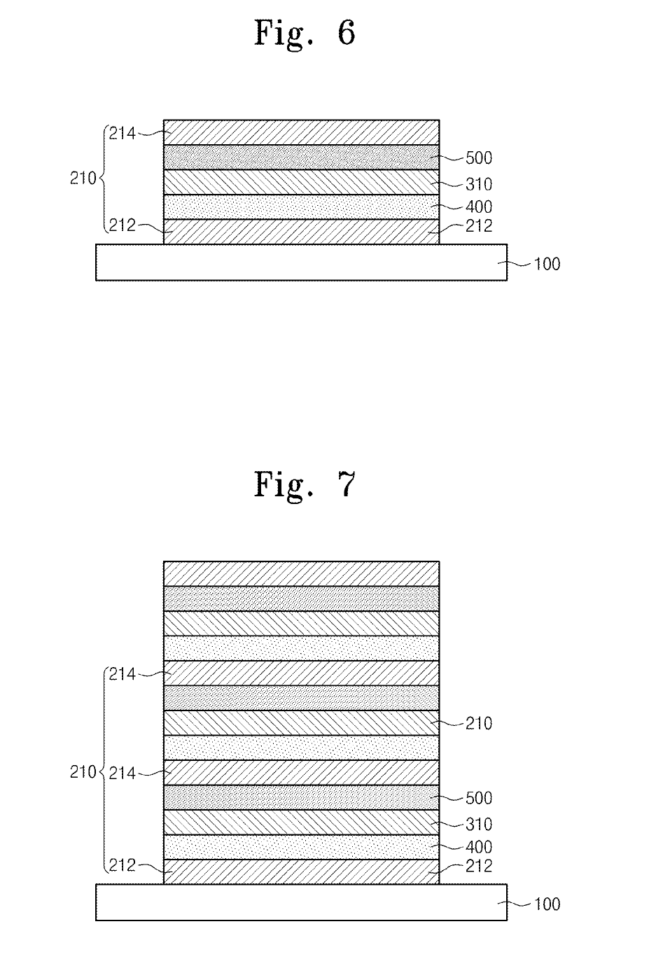

Referring to FIG. 7, the first thermoelectric medium layers 400, the low temperature-horizontal electrode layers 310, the second thermoelectric medium layers 500, and the upper high temperature-horizontal electrode layers 214 are sequentially formed on the upper high temperature-horizontal electrode layer 214.

The first thermoelectric medium layers 400, the low temperature-horizontal electrode layers 310, the second thermoelectric medium layers 500, and the upper high temperature-horizontal electrode layers 214 may be repetitively formed. The first thermoelectric medium layers 400, the low temperature-horizontal electrode layers 310, the second thermoelectric medium layers 500, and the upper high temperature horizontal electrode layers 214 may be patterned through a photolithography process and an etching process.

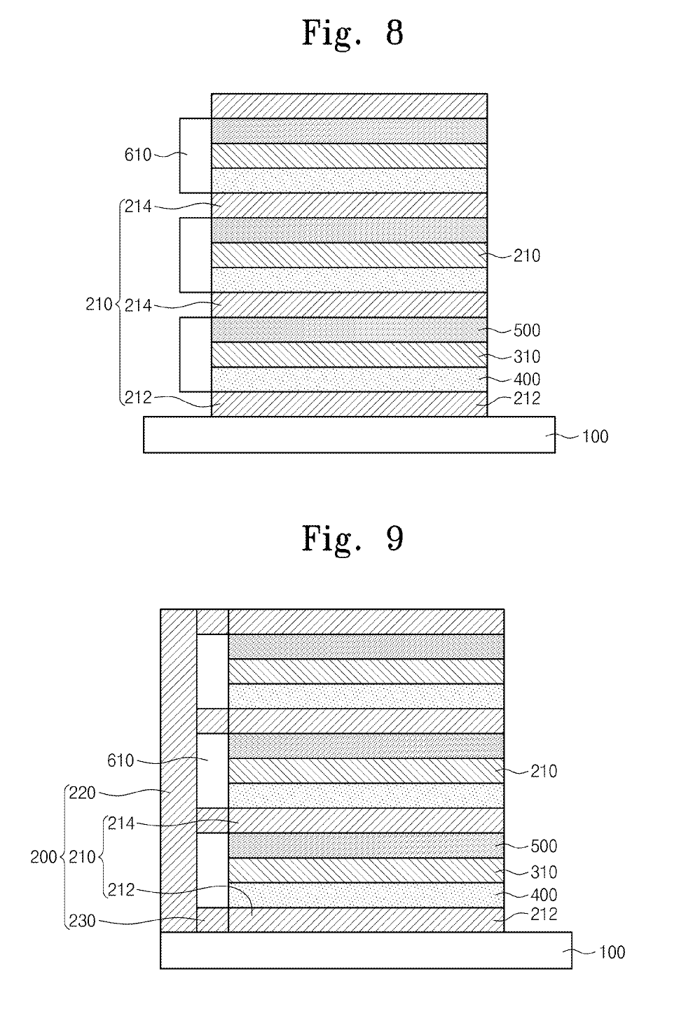

Referring to FIG. 8, the first insulating layers 610 are formed on one sidewalls of the first thermoelectric medium layers 400, the low temperature horizontal electrode layers 310, and the second thermoelectric medium layers 500.

The first insulating layers 610 may be formed through a deposition process, a photolithography process, and an etching process. The vapor deposition process may include chemical vapor deposition. As an example, the substrate 100, the lower high temperature-horizontal electrode layer 212, the first thermoelectric medium layers 400, the low temperature-horizontal electrode layers 310, the second thermoelectric medium layers 500, and the upper high temperature-horizontal electrode layers 214 may rotate in an azimuthal direction of about 90° during the deposition process. The one sidewalls of the high temperature-horizontal electrode layers 210 may be exposed from the first insulating layers 610 through a photolithography process.

Referring to FIG. 9, the high temperature edge electrode layers 230 and the high temperature-vertical electrode 220 are formed on the one sidewalls of the high temperature-horizontal electrode layers 210 and the first insulating layers 610, respectively.

The high temperature edge electrode layers 230 and the high temperature-vertical electrode 220 may be formed through a metal deposition process and a photolithography process.

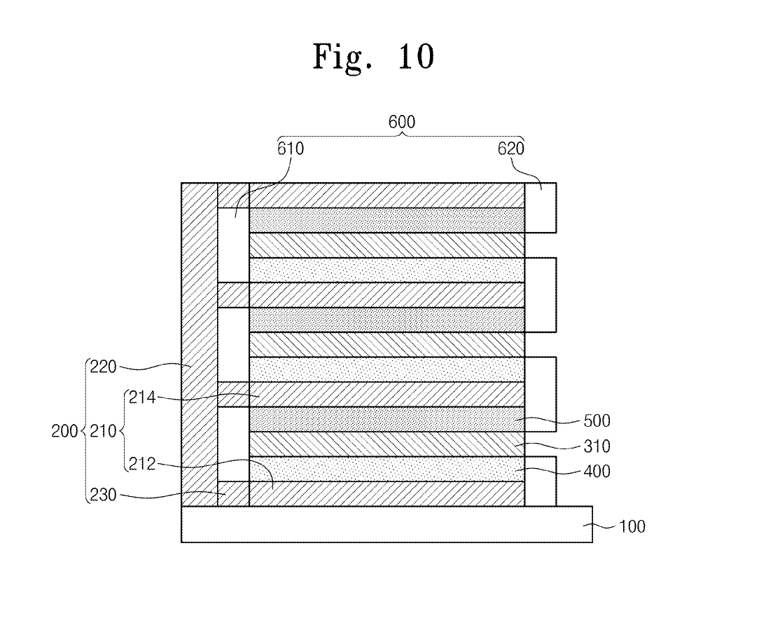

Referring to FIG. 10, the second insulating layers 620 are formed on the other sidewalls of the high temperature-horizontal electrode layers 210, the first thermoelectric medium layers 400, and the second thermoelectric medium layers 500. The forming of the second insulating layers 620 may include a deposition process, a photolithography process, and an etching process. The deposition process may include chemical vapor deposition. As an example, the substrate 100, the lower high temperature-horizontal electrode layer 212, the first thermoelectric medium layers 400, the low temperature-horizontal electrode layers 310, the second thermoelectric medium layers 500, and the upper high temperature-horizontal electrode layers 214 may rotate in an azimuthal direction of about 270° during the deposition process.

Referring to FIG. 1, the low temperature edge electrode layers 330 and the low temperature-vertical electrode 320 are formed on the other sidewalls of the low temperature-horizontal electrode layers 310 and the second insulating layers 620, respectively. The forming of the low temperature edge electrode layers 330 and the low temperature-vertical electrode 320 may include a metal deposition process and a photolithography process.

### Embodiment 2

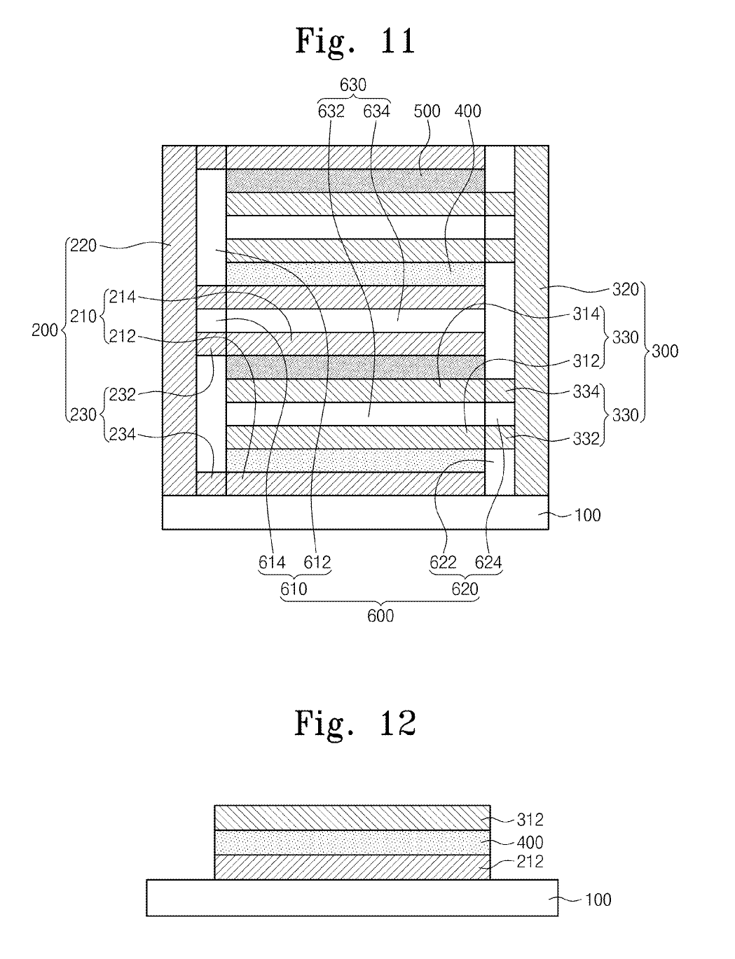

FIG. 11 is a cross-sectional view of a thermoelectric device according to another embodiment of the inventive concept.

Referring to FIG. 11, an insulating layer 600 of the thermoelectric device of FIG. 11 may include interlayer dielectrics 630.

The interlayer dielectrics 630 may include first interlayer dielectrics 632 and second interlayer dielectrics. The first interlayer dielectrics 632 may be disposed between the low temperature-horizontal electrode layers 310. The second interlayer dielectrics 634 may be disposed between the high temperature-horizontal electrode layers 210.

The low temperature-horizontal electrode layers 310 may include lower low temperature-horizontal electrode layers 312 and upper low temperature horizontal electrode layers 314. As an example, the lower low temperature horizontal electrode layers 312 and the upper low temperature-horizontal electrode layers 314 may be disposed on tops and bottoms of the first interlayer dielectrics 632. For example, the lower low temperature-horizontal electrode layers 312 may be disposed between the first thermoelectric medium layers 400 and the first interlayer dielectrics 632. The upper low temperature-horizontal electrode layers 314 may be disposed between the first interlayer dielectrics 632 and the second thermoelectric medium layers 500.

The high temperature-horizontal electrode layers 210 may include the lower low temperature-horizontal electrode layers 212 and the upper low temperature-horizontal electrode layers 214. As an example, the lower high temperature-horizontal electrode layers 212 and the upper high temperature horizontal electrode layers 214 may be disposed on tops and bottoms of the second interlayer dielectrics 634. For example, the lower high temperature-horizontal electrode layers 212 may be disposed between the second interlayer dielectric 634 and the first thermoelectric medium layer 400. Also, the lower high temperature horizontal electrode layers 212 may be disposed between the substrate 100 and the first thermoelectric medium layers 400. The upper high temperature-horizontal electrode layers 214 may be disposed between the second thermoelectric medium layers 500 and the second interlayer dielectric 634.

The high temperature edge electrode layers 230 may be disposed between the high temperature-horizontal electrode layers 210 and the high temperature-vertical electrode 220. The high temperature edge electrode layers 230 may include lower high temperature edge electrode layers 232 and upper high temperature edge electrode layers 234.

The lower high temperature edge electrode layers 232 may be disposed between the lower high temperature-horizontal electrode layers 210 and the high temperature-vertical electrode 220. The upper high temperature edge electrode layers 234 may be disposed between the upper high temperature-horizontal electrode layers 214 and the high temperature-vertical electrode 220.

The low temperature-horizontal electrode layers 310 may include the lower low temperature-horizontal electrode layers 312 and the upper low temperature-horizontal electrode layers 314. As an example, the lower low temperature-horizontal electrode layers 312 and the upper low temperature horizontal electrode layers 314 may be disposed on tops and bottoms of the first interlayer dielectrics 632. For example, the lower low temperature-horizontal electrode layers 312 may be disposed between the first interlayer dielectrics 632 and the first thermoelectric medium layers 400. The upper low temperature-horizontal electrode layers 314 may be disposed between the second thermoelectric medium layers 500 and the first interlayer dielectric 632.

The low temperature edge electrode layers 330 may be disposed between the low temperature-horizontal electrode layers 310 and the low temperature-vertical electrode 320. The low temperature edge electrode layers 330 may include lower low temperature edge electrode layers 332 and upper low temperature edge electrode layers 334. The low temperature edge electrode layers 332 may be disposed between the lower low temperature-horizontal electrode layers 312 and the low temperature-vertical electrode 320. The upper low temperature edge electrode layers 334 may be disposed between the upper low temperature-horizontal electrode layers 314 and the low temperature-vertical electrode 320.

The first insulating layers 610 may include first sidewall insulating layers 612 and first edge insulating layers 614. The first sidewall insulating layers 612 may be connected to the first interlayer dielectrics 632. The first edge insulating layers 614 may be connected to the second interlayer dielectrics 634.

The second insulating layers 620 may include second sidewall insulating layers 622 and second edge insulating layers 624. The second sidewall insulating layers 622 may be connected to the second interlayer dielectrics 634. The second edge insulating layers 624 may be connected to the first interlayer dielectrics 632.

In the second embodiment, in addition to the insulating layer 600 in the first embodiment, there are included the interlayer dielectrics 630 and the first edge insulating layers 614 and the second edge insulating layers 624 connected to the interlayer dielectrics 630, respectively.

A method of manufacturing the thermoelectric device of FIG. 11 formed as described above will be described as follows.

FIGS. 12 to 21 are cross-sectional views illustrating a process of manufacturing the thermoelectric device of FIG. 11.

Referring to FIGS. 12 and 13, the first thermoelectric medium layer 400 is formed on the lower high temperature-horizontal electrode layer 212.

Referring to FIG. 12, the lower low temperature-horizontal electrode layer 312 is formed on the first thermoelectric medium layer 400. The forming of the lower low temperature-horizontal electrode layer 312 may include a metal deposition process, a photolithography process, and an etching process.

Referring to FIG. 13, the first interlayer dielectric 632 is formed on the lower low temperature-horizontal electrode layer 312. The forming of the first interlayer dielectric 632 may include a chemical vapor deposition process, a photolithography process, and an etching process.

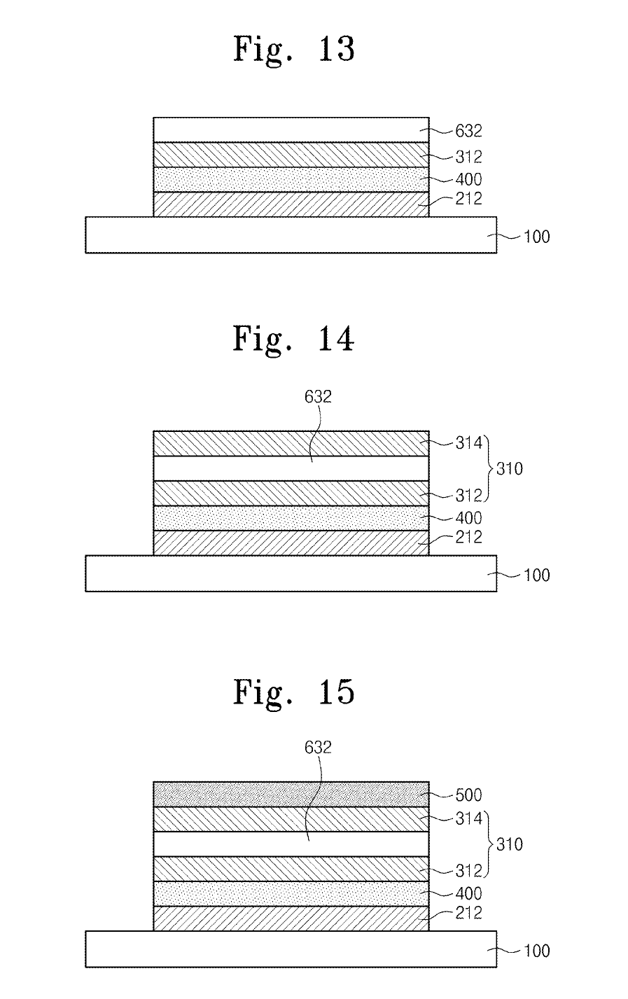

Referring to FIG. 14, the upper low temperature-horizontal electrode layer 314 is formed on the first interlayer dielectric 632. The forming of the upper low temperature-horizontal electrode layer 314 may include a metal deposition process, a photolithography process, and an etching process.

Referring to FIG. 15, the second thermoelectric medium layer 500 is formed on the upper low temperature-horizontal electrode layer 314. The forming of the second thermoelectric medium layer 500 may include a deposition process, a photolithography process, and an etching process. The deposition process may include spin casting, spin coating, or printing.

Referring to FIG. 16, the upper high temperature-horizontal electrode layer 214 is formed on the second thermoelectric medium layer 500. The forming of the upper high temperature-horizontal electrode layer 214 may include a metal deposition process, a photolithography process, and an etching process.

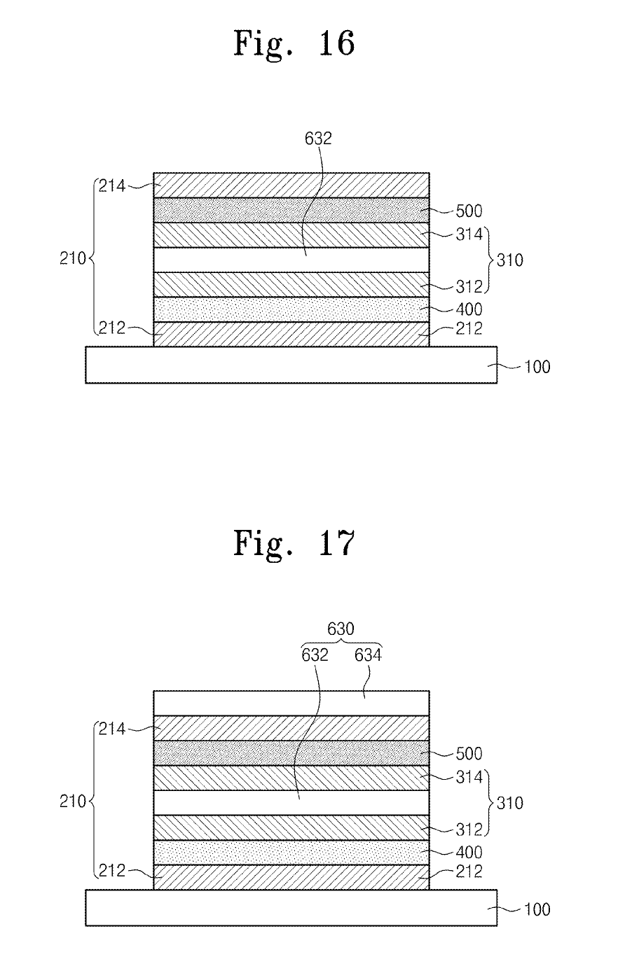

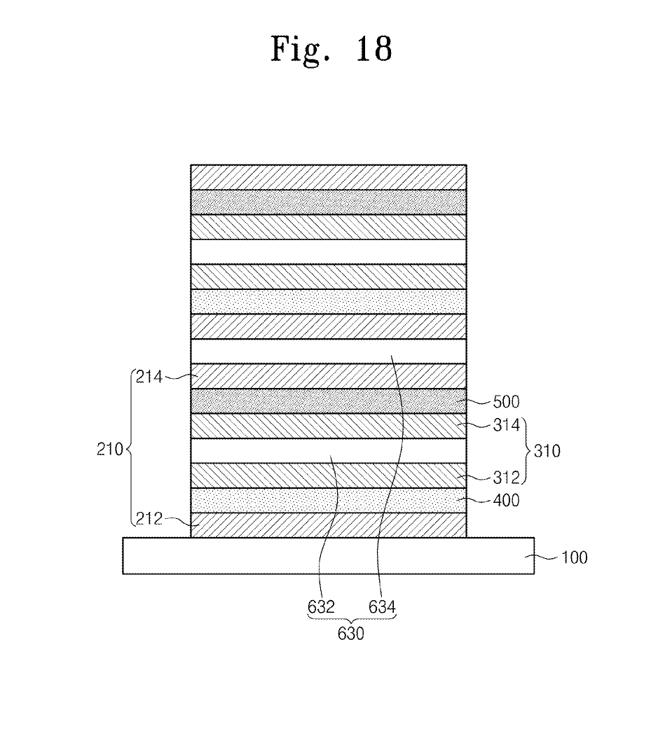

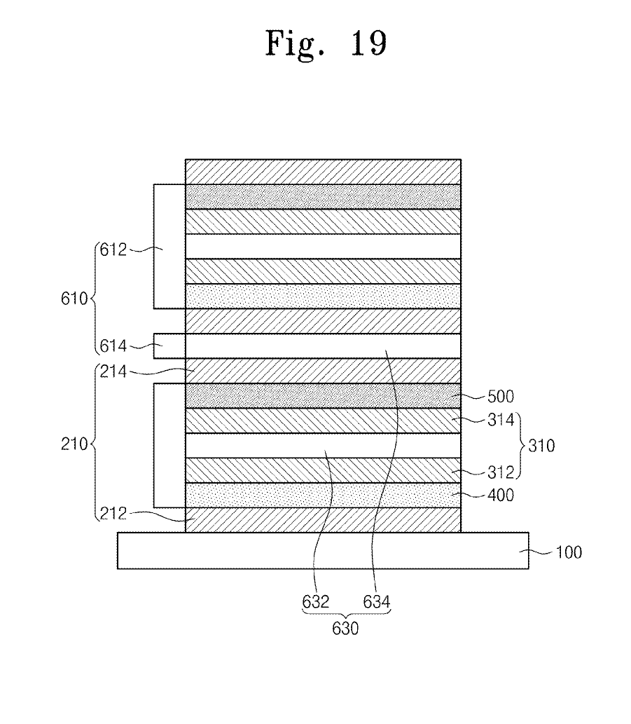

Referring to FIG. 17, the second interlayer dielectric 634 is formed on the upper high temperature-horizontal electrode layer 214. The forming of the second interlayer dielectric 634 may include a deposition process, a photolithography process, and an etching process.

Referring to FIG. 18, the lower high temperature-horizontal electrode layer 212, the first thermoelectric medium layer 400, the lower low temperature horizontal electrode layer 312, the first interlayer dielectric 632, the upper low temperature-horizontal electrode layer 314, the second thermoelectric medium layer 500, and the upper high temperature-horizontal electrode layer 214 are sequentially formed on the second interlayer dielectric 634.

Referring to FIG. 19, the first insulating layers 610 are formed on one sidewalls of the first thermoelectric medium layers 400, the lower low temperature-horizontal electrode layers 312, the first interlayer dielectrics 632, the upper low temperature-horizontal electrode layers 314, the second thermoelectric medium layers 500, the second interlayer dielectric 634, respectively. The forming of the first insulating layers 610 may include a deposition process, a photolithography process, and an etching process. The deposition process may include chemical vapor deposition. Herein, the substrate 100, the lower high temperature-horizontal electrode layers 212, the first thermoelectric medium layers 400, the lower low temperature-horizontal electrode layers 312, the first interlayer dielectrics 632, the upper low temperature-horizontal electrode layers 314, the second thermoelectric medium layers 500, the upper high temperature-horizontal electrode layers 214, and the second interlayer dielectric 634 may rotate in an azimuthal direction of about 90° during the deposition process for the first insulating layers 610.

The first insulating layers 610 may be patterned into the first sidewall insulating layers 612 and the first edge insulating layers 614 through a photolithography process and an etching process.

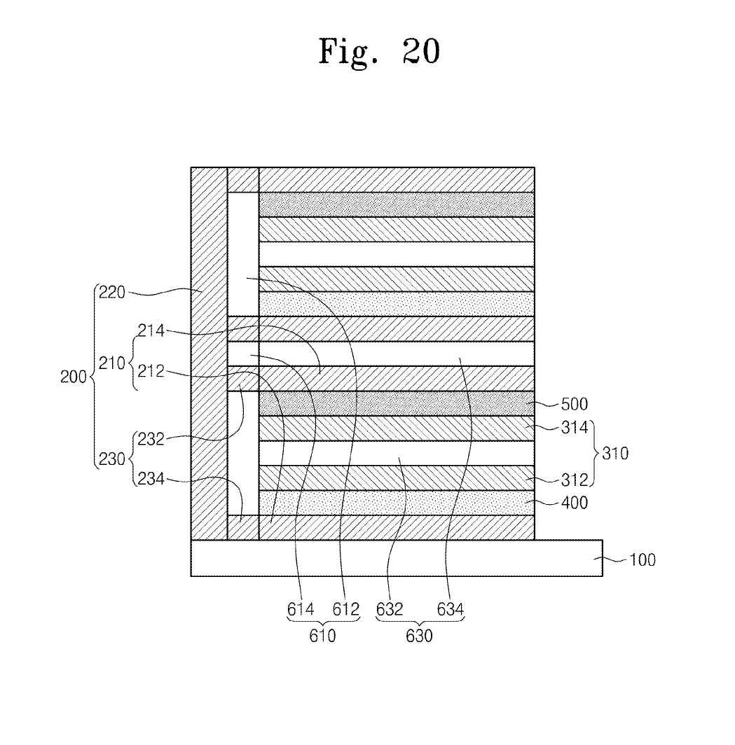

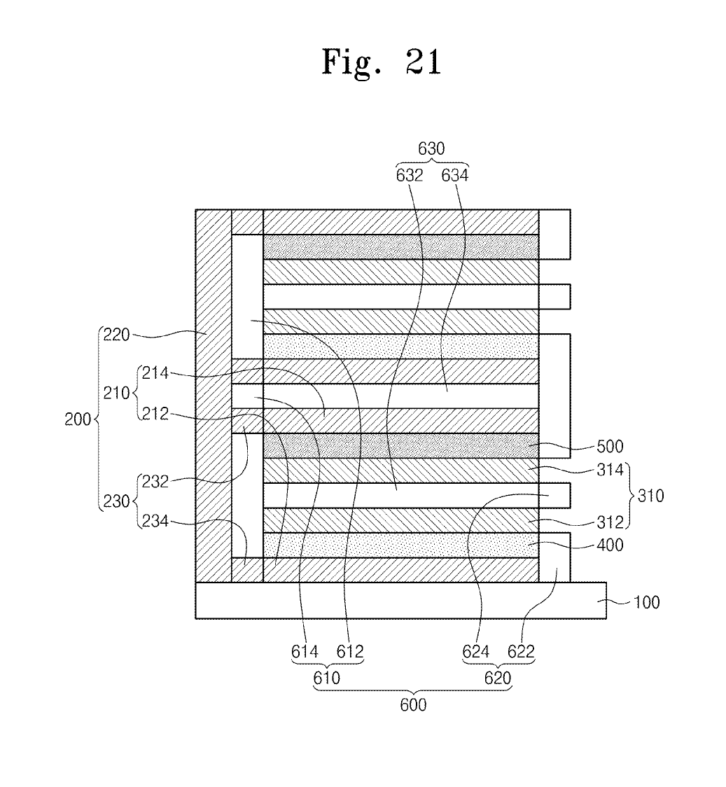

Referring to FIG. 20, the high temperature edge electrode layers 230 and the high temperature-vertical electrode 220 are formed on respective one sidewalls of the lower high temperature-horizontal electrode layers 212 and the upper high temperature-horizontal electrode layers 214 and the first insulating layers 610, respectively. The forming of the high temperature edge electrode layers 230 and the high temperature-vertical electrode 220 may include a metal deposition process, a photolithography process, and an etching process.

Referring to FIG. 21, the second insulating layers 620 are formed on other sidewalls of the lower high temperature-horizontal electrode layers 212, the first thermoelectric medium layers 400, the first interlayer dielectrics 632, the second thermoelectric medium layers 500, and the upper high temperature-horizontal electrode layers 214. The forming of the second insulating layers 620 may include a deposition process, a photolithography process, and an etching process. The substrate 100, the lower high temperature-horizontal electrode layers 212, the first thermoelectric medium layers 400, the lower low temperature-horizontal electrode layers 312, the first interlayer dielectrics 632, the upper low temperature-horizontal electrode layers 314, the second thermoelectric medium layers 500, the upper high temperature-horizontal electrode layers 214, and the second interlayer dielectric 634 may rotate in an azimuthal direction of about 270° during the deposition process for the second insulating layers 620.

The second insulating layers 620 may be patterned into the second sidewall insulating layers 622 and the second edge insulating layers 624 through a photolithography process and an etching process.

Referring to FIG. 11, the low temperature edge electrode layers 330 and the low temperature-vertical electrode 320 are formed on respective other sidewalls of the lower low temperature-horizontal electrode layers 312 and the upper low temperature-horizontal electrode layers 314 and the second insulating layers 620.

The forming of the low temperature edge electrode layers 330 and the low temperature-vertical electrode 320 may include a metal deposition process, a photolithography process, and an etching process.

As described above, according to the exemplary embodiments, a thermoelectric device may include a substrate, a first electrode, a second electrode, first thermoelectric medium layers, and second thermoelectric medium layers. The first electrode may have a comb shape connected to one side of the substrate and open to another side of the substrate. The second electrode may be inserted into the first electrode and may have a comb shape connected to the other side of the substrate and open to the one side of the substrate. The first and second thermoelectric medium layers may be alternately disposed between the first electrode and the second electrode in a direction of being further from the substrate. The first electrode, the first thermoelectric medium layers, the second electrode, and the second thermoelectric medium layers may be deposited to be vertical to the substrate. Accordingly, the first electrode, the second electrode, the first thermoelectric medium layers, and the second thermoelectric medium layers may reduce a unit cell area of the thermoelectric device.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thermoelectric device comprising:
a substrate;
a first electrode having a first comb shape connected to one side of the substrate and open to the other side of the substrate;
a second electrode having a second comb shape connected to the other side of the substrate and open to the one side of the substrate, the second electrode inserted into the first electrode; and
first and second thermoelectric medium layers disposed between the first electrode and the second electrode and alternately disposed in a direction apart from the substrate.

2. The thermoelectric device of claim 1, wherein the first electrode comprises:
first horizontal electrode layers parallel to the substrate; and
a first vertical electrode connecting the first horizontal electrode layers in a direction vertical to the substrate.

3. The thermoelectric device of claim 2, wherein the first electrode further comprises first edge electrode layers between the first horizontal electrode layers and the first vertical electrode.

4. The thermoelectric device of claim 3, wherein the second electrode comprises:
second horizontal electrode layers parallel to the substrate and disposed between the first horizontal electrode layers; and
a second vertical electrode parallel to the first vertical electrode and connecting the second horizontal electrode layers in the direction vertical to the substrate.

5. The thermoelectric device of claim 4, wherein the second electrode further comprises second edge electrode layers between the second horizontal electrode layers and the second vertical electrode.

6. The thermoelectric device of claim 5, further comprising an insulating layer between the first electrode and the second electrode.

7. The thermoelectric device of claim 6, wherein the insulating layer comprises:
a first insulating layer between the first edge electrode layers; and
a second insulating layer between the second edge electrode layers.

8. The thermoelectric device of claim 7, wherein the first and second thermoelectric medium layers are alternately disposed between the first horizontal electrode layers and the second horizontal electrode layers, respectively.

9. The thermoelectric device of claim 8, wherein the first horizontal electrode layers comprise:
a first lower horizontal electrode layer between the substrate and the first thermoelectric medium layers; and
first upper horizontal electrode layers between the second thermoelectric medium layers and the first thermoelectric medium layer.

10. The thermoelectric device of claim 7, wherein the insulating layer further comprises an interlayer dielectric, and
wherein the interlayer dielectric comprises:
a first interlayer dielectric between the first horizontal electrode layers; and
a second interlayer dielectric between the second horizontal electrode layers.

11. The thermoelectric device of claim 10, wherein the first horizontal electrode layers comprise:
first lower horizontal electrode layers between the substrate and the first thermoelectric medium layers or between the second interlayer dielectric and the first thermoelectric medium layers; and
first upper horizontal electrode layers between the second thermoelectric medium layers and the second interlayer dielectric.

12. The thermoelectric device of claim 11, wherein the first edge electrode layers comprise:
first lower edge electrode layers connecting the first lower horizontal electrode layers to the first vertical electrode; and
first upper edge electrode layers connecting the first upper horizontal electrode layers to the first vertical electrode.

13. The thermoelectric device of claim 10, wherein the second horizontal electrode layers comprise:
second lower horizontal electrode layers between the first thermoelectric medium layers and the first interlayer dielectrics; and
second upper horizontal electrode layers between the first interlayer dielectrics and the second thermoelectric medium layers.

14. The thermoelectric device of claim 13, wherein the second edge electrode layers comprise:
second lower edge electrode layers connecting the second lower horizontal electrode layers to the second vertical electrode; and
second upper edge electrode layers connecting the second upper horizontal electrode layers to the second vertical electrode.

15. The thermoelectric device of claim 10, wherein the first insulating layer comprises:
a first sidewall insulating layer disposed between one sidewalls of the first thermoelectric medium layers, the first low temperature-horizontal electrode layers and the second thermoelectric medium layers and the first vertical electrode and connected to one side of the first interlayer dielectric; and
a first edge insulating layer disposed between one side of the second interlayer dielectric and the first vertical electrode.

16. The thermoelectric device of claim 10, wherein the second insulating layer comprises:
a second edge insulating layer disposed between other sidewalls of the second thermoelectric medium layers, the first high temperature-horizontal electrode layers and the first thermoelectric medium layers and the second vertical electrode and connected to another side of the second interlayer dielectric; and
a second sidewall insulating layer disposed between another side of the second interlayer dielectric and the second vertical electrode.

17. A thermoelectric device comprising:
a plurality of first and second horizontal electrodes alternately stacked on a substrate;
a plurality of first and second thermoelectric medium layers alternately disposed between the first and second horizontal electrodes;
a first vertical electrode connecting the first horizontal electrodes; and
a second vertical electrode parallel to the first vertical electrode and connecting the second horizontal electrodes.

18. The thermoelectric device of claim 17, further comprising:
a first insulating layer between the second horizontal electrodes and the first vertical electrode; and
a second insulating layer between the first horizontal electrodes and the second vertical electrode.

19. A method of manufacturing a thermoelectric device, comprising:
forming first thermoelectric medium layers on first horizontal electrode layers;
forming second horizontal electrode layers on the first thermoelectric medium layers;
forming second thermoelectric medium layers on the second horizontal electrode layers;
repetitively forming the first horizontal electrode layers, the first thermoelectric medium layers, the second horizontal electrode layers, the second thermoelectric medium layers, and the first horizontal electrode layers on the second thermoelectric medium layers;
forming a first insulating layer on respective sidewalls of the first thermoelectric medium layer, the second horizontal electrode layer, and the second thermoelectric medium layer;
forming first edge electrode layers and a first vertical electrode on one sidewalls of the first horizontal electrode layers exposed from the first insulating layer and the first insulating layer;
forming a second insulating layer on respective other sidewalls of the first horizontal electrode layers, the first thermoelectric medium layers, and the second thermoelectric medium layers; and
forming second edge electrode layers and a second vertical electrode on other sidewalls of the second horizontal electrode layers exposed from the second insulating layer and the second insulating layer.

20. The method of claim 19, further comprising:
forming first interlayer dielectrics between the first horizontal electrode layers; and
forming second interlayer dielectrics between the second horizontal electrode layers.
